(19) United States
(12) Patent Application Publication
(10) Pub. No.: US 2020/0027816 A1
(43) Pub. Date: Jan. 23, 2020

(54) TRANSMISSION DEVICE AND PLUG-IN UNIT

(71) Applicant: FUJITSU LIMITED, Kawasaki-shi (JP)

(72) Inventors: Shota MORIMOTO, Yokohama (JP); Minoru FUJII, Kawasaki (JP); Kenji JOKO, Yokohama (JP); HIROFUMI IMABAYASHI, Kawasaki (JP)

(73) Assignee: FUJITSU LIMITED, Kawasaki-shi (JP)

(21) Appl. No.: 16/457,087

(22) Filed: Jun. 28, 2019

(30) Foreign Application Priority Data
Jul. 19, 2018 (JP) 2018-136164

(51) Int. Cl. H01L 23/40; H01L 23/36; G02B 6/38

(52) U.S. Cl. CPC H01L 23/40; G02B 6/3807; H01L 23/36

(57) ABSTRACT

A transmission device includes a first substrate on which a heat generation component is arranged, a heat sink that is placed on the heat generation component, a second substrate that is arranged above a surface of the first substrate on which the heat generation component is arranged and a pressing mechanism that presses the heat sink against the heat generation component arranged on the first substrate from the second substrate side.

### CROSS-REFERENCE TO RELATED APPLICATION

This application is based upon and claims the benefit of priority of the prior Japanese Patent Application No. 2018-136164, filed on Jul. 19, 2018, the entire contents of which are incorporated herein by reference.

### FIELD

The embodiments discussed herein are related to a transmission device and a plug-in unit.

### BACKGROUND

In a plug-in unit (PIU) to which an optical transmission line is connectable and a blade-type transmission device into which the PIU is inserted, an electronic component as a heat generation component is mounted in a space in a housing. Heat generated from the heat generation component causes operation abnormality to occur in the PIU and the transmission device. For this reason, a heat sink for prompting heat dissipation is attached to the heat generation component in many cases.

When the heat sink is attached to the heat generation component, for example, a base member is arranged on a substrate on which the heat generation component is arranged so as to surround the heat generation component and the heat sink is fastened to the base member, so that the heat sink is pressed against the heat generation component. It is, however, difficult to ensure a region for mounting another component around the heat generation component when the base member is arranged around the heat generation component.

Therefore, various techniques of pressing the heat sink against the heat generation component without arranging the base member around the heat generation component have been studied. For example, there is an existing technique in which a pair of columns is provided at positions interposing a heat generation component on a substrate on which the heat generation component is arranged and a heat sink is pressed against the heat generation component from a beam member bridged between the pair of columns with a bolt member interposed therebetween.

Japanese Laid-open Patent Publication No. 2013-55176 is an example of related art.

However, in the above-described existing technique, the pair of columns is arranged around the heat generation component and a sufficient region for mounting another component is therefore not ensured around the heat generation component.

In view of the above-described circumstances, it is desirable to provide a transmission device and a plug-in unit capable of ensuring a sufficient region for mounting another component around a heat generation component against which a heat sink is pressed.

### SUMMARY

According to an aspect of the embodiments, an apparatus includes a transmission device includes a first substrate on which a heat generation component is arranged, a heat sink that is placed on the heat generation component, a second substrate that is arranged above a surface of the first substrate on which the heat generation component is arranged and a pressing mechanism that presses the heat sink against the heat generation component arranged on the first substrate from the second substrate side.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating an appearance of a transmission device according to a first embodiment;

FIG. 2 is a perspective view illustrating an example of the internal configuration of a PIU according to the first embodiment;

FIG. 3 is a front view illustrating an example of the internal configuration of the PIU according to the first embodiment;

FIG. 4 is a side cross-sectional view illustrating an example of the configuration of a pressing mechanism according to the first embodiment;

FIG. 5 is a view (part 1) for explaining a function of a first buffer member;

FIG. 6 is a view (part 2) for explaining the function of the first buffer member;

FIG. 7 is a perspective view illustrating an example of the internal configuration of a PIU according to a second embodiment;

FIG. 8 is a front view illustrating an example of the internal configuration of the PIU according to the second embodiment;

FIG. 9 is a side cross-sectional view illustrating an example of the configuration of a pressing mechanism according to the second embodiment;

FIG. 10 is a view (part 1) for explaining functions of the first buffer member and a second buffer member;

FIG. 11 is a view (part 2) for explaining the functions of the first buffer member and the second buffer member;

FIG. 12 is a perspective view illustrating an example of the internal configuration of a PIU according to a third embodiment;

FIG. 13 is a front view illustrating an example of the internal configuration of the PIU according to the third embodiment;

FIG. 14 is a side cross-sectional view illustrating an example of the configuration of a pressing mechanism according to the third embodiment; and

FIG. 15 is a view for explaining a function of a third buffer member.

### DESCRIPTION OF EMBODIMENTS

Hereinafter, embodiments of a transmission device and a plug-in unit disclosed by the present application will be described in detail with reference to the drawings. The embodiments do not limit the disclosed technique. In the embodiments, the same reference numerals denote components having the same functions and overlapped description thereof is omitted.

### First Embodiment

[Configuration of Transmission Device 1]

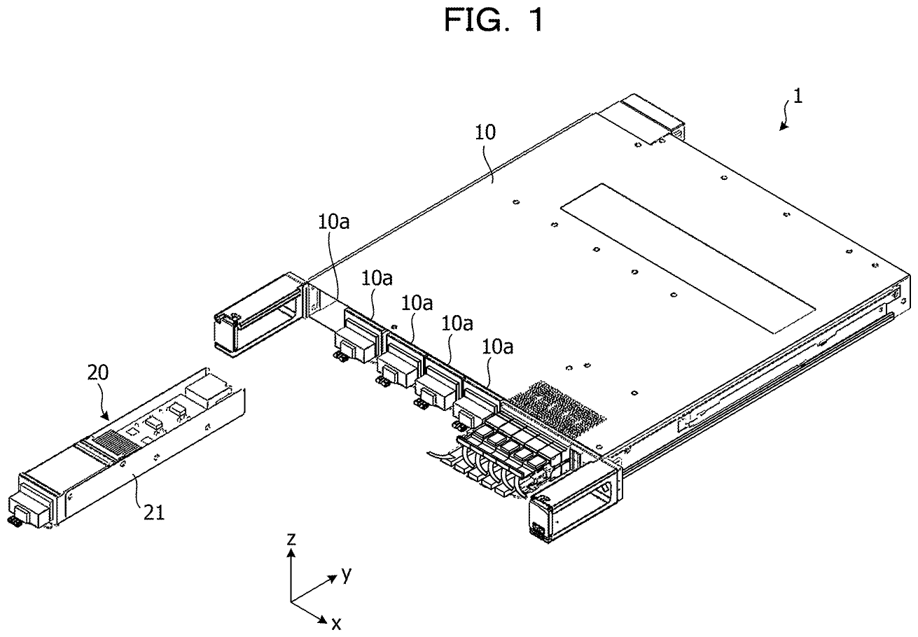

FIG. 1 is a perspective view illustrating an appearance of a transmission device 1 according to a first embodiment. The transmission device 1 illustrated in FIG. 1 is, for example, a blade-type transmission device that is attached to a rack (not illustrated) in a detachable manner. A plug-in unit (PIU) 20 to which an optical transmission line is connectable is inserted into the transmission device 1. The transmission device 1 has a housing 10. The housing 10 is a box body having a bottom plate, a top plate opposing the bottom plate, a pair of opposing side walls, a front surface, and a rear surface. Hereinafter, the bottom plate and the top plate of the housing 10 are parallel to an xy plane, the pair of side walls of the housing 10 is parallel to an yz plane, and the front surface and the rear surface of the housing 10 are parallel to an xz plane. An x direction is referred to as a width direction of the housing 10, a y direction is referred to as a depth direction of the housing 10, and a z direction is referred to as a height direction of the housing 10. A direction indicated by an arrow of a z axis is referred to as an upward direction and a direction opposite to the direction indicated by the arrow of the z axis is referred to as a downward direction. A direction indicated by an arrow of a y axis is referred to as a back side and a direction opposite to the direction indicated by the arrow of the y axis is referred to as a front side. The surface of the housing 10 on the front side is the front surface of the housing 10 and the surface of the housing 10 on the back side is the rear surface of the housing 10.

As illustrated in FIG. 1, a plurality of slots 10a is formed in the front surface of the housing 10. In the example illustrated in FIG. 1, five slots 10a are formed. The PIU 20 is inserted into each of the slots in the front surface of the housing 10. Insertion of the PIU 20 into each of the slots in the front surface of the housing 10 causes the PIU 20 to be electrically connected to a printed circuit board arranged in the housing 10.

[Configuration of PIU 20]

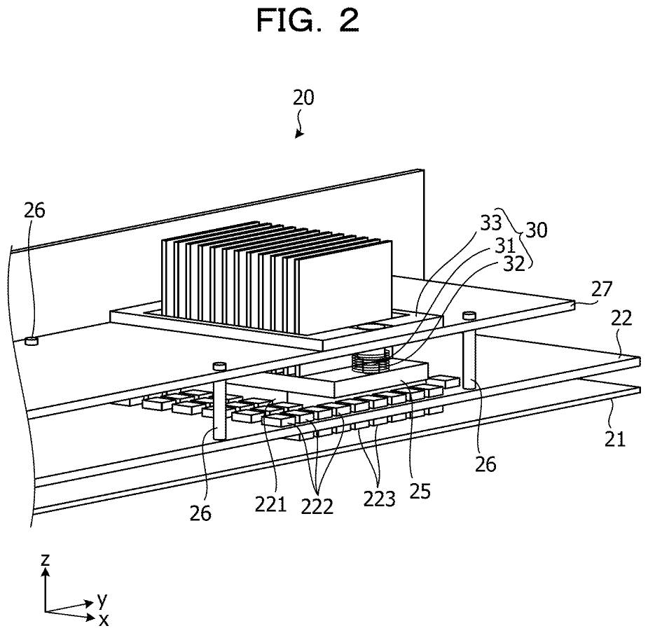

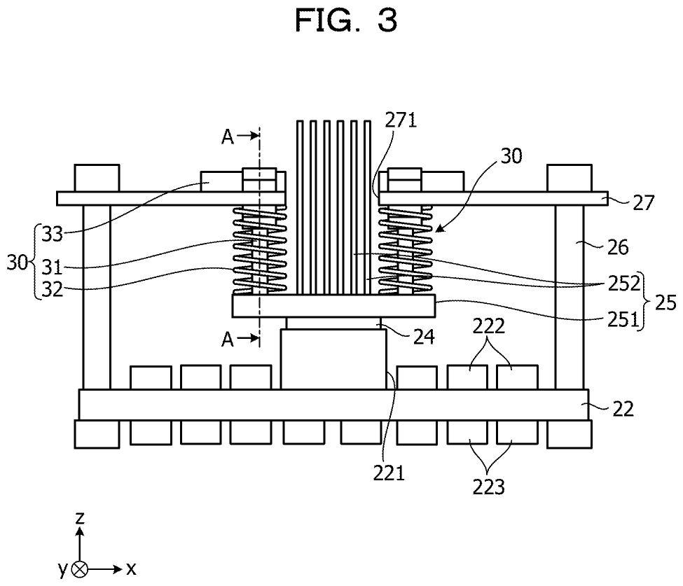

FIG. 2 is a perspective view illustrating an example of an internal configuration of the PIU 20 according to the first embodiment. FIG. 3 is a front view illustrating an example of the internal configuration of the PIU 20 according to the first embodiment.

As illustrated in FIG. 1 and FIG. 2, the PIU 20 has a housing 21 that may be inserted into and removed from the housing 10. In FIG. 3, the housing 21 is omitted for the convenience of explanation. As illustrated in FIG. 2 and FIG. 3, a main substrate 22 as a printed circuit board is fixed in the housing 21. A heat generation component 221 as an electronic component generating heat in operation is arranged on the upper surface of the main substrate 22. A plurality of electronic components 222 having lower heating values than the heat generation component 221 is arranged in a region surrounding the heat generation component 221 on the upper surface of the main substrate 22. A plurality of electronic components 223 having lower heating values than the heat generation component 221 is arranged on the lower surface of the main substrate 22. The main substrate 22 is an example of a first substrate.

A heat sink 25 is placed on the upper surface of the heat generation component 221 with a heat conductive sheet 24 interposed therebetween. The heat sink 25 has a main body portion 251 and fin portions 252. The heat sink 25 is disposed along the upper surface of the heat generation component 221. The fin portions 252 are provided so as to stand from the upper surface of the main body portion 251, passes through a cavity 271 in a sub substrate 27, which will be described later, and extends to the upper side of the sub substrate 27. With this configuration, the heat sink 25 may enlarge heat dissipation areas of the fin portions 252 as large as possible to thereby dissipate heat generated from the heat generation component 221 efficiently.

The sub substrate 27 as a printed circuit board is arranged above the upper surface of the main substrate 22, for example, above the surface of the main substrate 22 on which the heat generation component 221 is arranged. The sub substrate 27 is arranged above the surface of the main substrate 22 on which the heat generation component 221 is arranged by being supported by column members 26 standing from the main substrate 22. The sub substrate 27 is electrically connected to the main substrate 22 with a cable (not illustrated) or the like. The cavity 271 through which the fin portions 252 of the heat sink 25 are inserted is formed in the sub substrate 27. The sub substrate 27 is an example of a second substrate.

The PIU 20 includes pressing mechanisms 30. The pressing mechanisms 30 are mechanisms that press the heat sink 25 against the heat generation component 221 arranged on the upper surface of the main substrate 22 from the side of the sub substrate 27 arranged above the upper surface of the main substrate 22. The pressing mechanisms 30 are arranged on the sub substrate 27 at each of the two positions interposing the fin portions 252 of the heat sink 25 therebetween. Although the arrangement positions of the pressing mechanisms 30 are two, the number of arranged pressing mechanisms 30 is not limited to two and may be equal to or more than three.

[Configuration of Pressing Mechanisms 30]

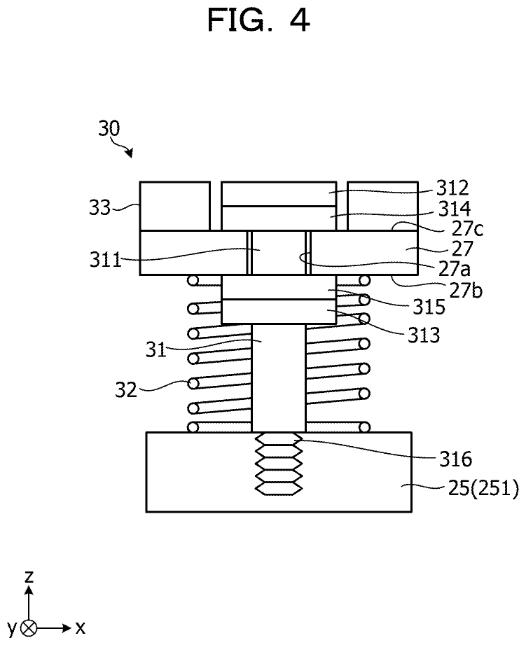

FIG. 4 is a side cross-sectional view illustrating an example of the configuration of the pressing mechanism 30 according to the first embodiment. The side cross-sectional view illustrated in FIG. 4 corresponds to a cross-sectional view cut along arrows A-A in FIG. 3. As illustrated in FIG. 2 to FIG. 4, the pressing mechanisms 30 include columnar members 31, springs 32, and reinforcing plates 33.

The columnar member 31 has a base end 311 arranged on the sub substrate 27, extends to the lower side of the sub substrate 27, and is engaged with the heat sink 25.

The spring 32 is provided so as to be wound around the outer circumference of the columnar member 31. The spring 32 abuts against a lower surface 27b of the sub substrate 27, which opposes the main substrate 22, and the heat sink 25 (main body portion 251) to press the heat sink 25 against the heat generation component 221 along the extension direction of the columnar member 31 with elastic force. The pressing mechanism 30 may thereby press the heat sink 25 against the heat generation component 221 from the sub substrate 27 side without arranging other members such as, a base member, a column, or the like, around the heat generation component 221 on the main substrate 22. As a result, a region for mounting another component (for example, electronic components 222) may be sufficiently ensured around the heat generation component 221 against which the heat sink 25 is pressed. The spring 32 is an example of an elastic member.

The reinforcing plate 33 covers at least a region of an upper surface 27c of the sub substrate 27 on the opposite side to the main substrate 22, which correspond to the spring 32. In the embodiment, the reinforcing plate 33 covers not only the region of the upper surface 27c of the sub substrate 27, which corresponds to the spring 32, but also an overall region thereof around the cavity 271. Coverage of the region of the upper surface 27c of the sub substrate 27, which corresponds to the spring 32, by the reinforcing plate 33 suppresses deflection of the sub substrate 27 with the elastic force of the spring 32.

An arrangement mode of the columnar member 31 on the sub substrate 27 and an engagement mode between the columnar member 31 and the heat sink 25 will be described in detail with reference to FIG. 4. A hole 27a through which the base end 311 of the columnar member 31 is inserted is formed in the sub substrate 27. A screw groove (not illustrated) is formed in the base end 311 of the columnar member 31. The columnar member 31 is fixed to the sub substrate 27 by mounting an upper nut member 312 and a lower nut member 313 as a pair of nut members on the base end 311 inserted through the hole 27a of the sub substrate 27 so as to interpose the sub substrate 27 therebetween.

Buffer members are inserted through between each of the upper nut member 312 and the lower nut member 313 and the sub substrate 27. For example, an upper buffer member 314 is inserted through between the upper nut member 312 and the upper surface 27c of the sub substrate 27 and a lower buffer member 315 is inserted through between the lower nut member 313 and the lower surface 27b of the sub substrate 27. The upper buffer member 314 and the lower buffer member 315 have functions of absorbing force which acts on the heat sink 25 in the gravity direction (up-down direction in FIG. 4) and is transmitted to the columnar member 31. The functions of the upper buffer member 314 and the lower buffer member 315 will be described in detail later. The upper buffer member 314 and the lower buffer member 315 are examples of a first buffer member.

The columnar member 31 includes a screw portion 316 which is engaged with a screw hole formed in the heat sink 25. Engagement between the screw portion 316 and the screw hole formed in the heat sink 25 avoids positional deviation between the columnar member 31 and the heat sink 25 and the elastic force of the spring 32 is efficiently transmitted to the heat sink 25 along the extension direction of the columnar member 31.

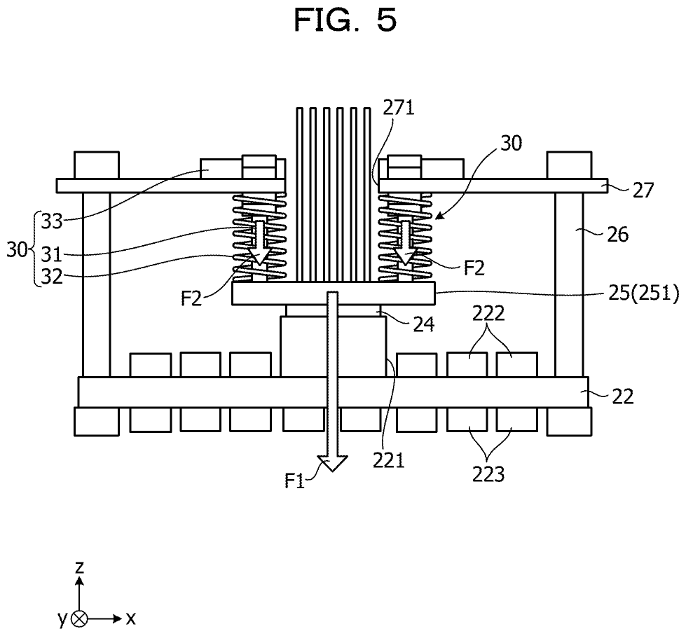

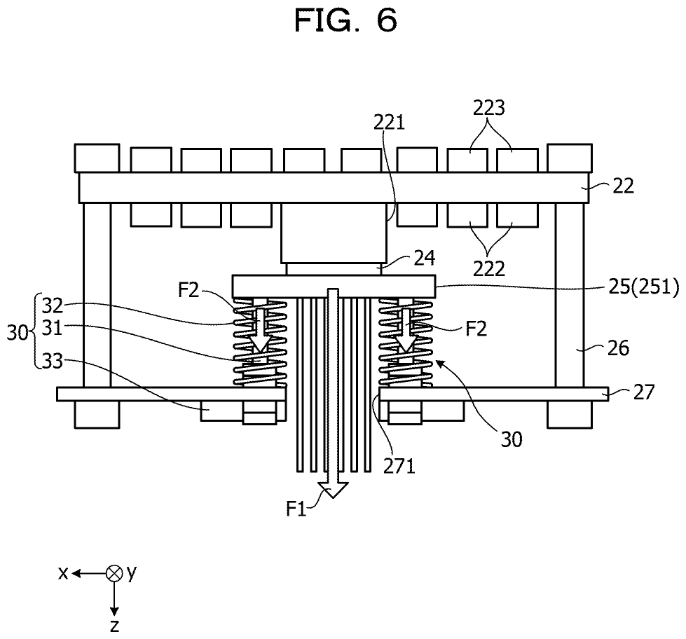

Next, the functions of the upper buffer members 314 and the lower buffer members 315 as the first buffer member will be described with reference to FIG. 5 and FIG. 6. FIG. 5 is a view (part 1) for explaining the function of the first buffer member. FIG. 5 illustrates a mode in which the PIU 20 falls on the ground in a state where the upper surface of the main substrate 22 (for example, surface of main substrate 22 on which heat generation component 221 is arranged) faces the direction on the opposite side to the ground. When the PIU 20 falls on the ground in the mode illustrated in FIG. 5, force F1 acts on the heat sink 25 in the gravity direction (downward direction in FIG. 5). The force F1 is transmitted, as forces F2, to the columnar members 31 engaged with the heat sink 25 and the upper nut members 312 mounted on the base ends 311 of the columnar members 31. When the forces F2 are transmitted to the upper nut members 312, the upper buffer members 314 inserted through between the upper nut members 312 and the upper surface 27c of the sub substrate 27 elastically contract and absorb the forces F2. The upper buffer members 314 may thereby suppress movement of the heat sink 25 in the gravity direction (downward direction in FIG. 5). As a result, impact that is applied to the heat generation component 221 from the heat sink 25 is relieved.

FIG. 6 is a view (part 2) for explaining the function of the first buffer member. FIG. 6 illustrates a mode in which the PIU 20 falls on the ground in a state where the upper surface of the main substrate 22 (for example, surface of main substrate 22 on which heat generation component 221 is arranged) faces the direction of the ground. When the PIU 20 falls on the ground in the mode illustrated in FIG. 6, force F1 acts on the heat sink 25 in the gravity direction (downward direction in FIG. 6). The force F1 is transmitted, as forces F2, to the columnar members 31 engaged with the heat sink 25 and the lower nut members 313 mounted on the base ends 311 of the columnar members 31. When the forces F2 are transmitted to the lower nut members 313, the lower buffer members 315 inserted through between the lower nut members 313 and the lower surface 27b of the sub substrate 27 elastically contract and absorb the forces F2. The lower buffer members 315 may thereby suppress movement of the heat sink 25 in the gravity direction (downward direction in FIG. 6) and avoid contraction of the springs 32 with the movement of the heat sink 25. As a result, the phenomenon (so-called bumping) that the heat sink 25 and the heat generation component 221 collide with each other with restoration of the springs 32 is avoided.

As described above, the transmission device 1 and the PIU 20 according to the embodiment include the pressing mechanisms 30 that press the heat sink 25 against the heat generation component 221 arranged on the upper surface of the main substrate 22 from the sub substrate 27 side arranged above the upper surface of the main substrate 22.

With the configurations of the transmission device 1 and the PIU 20, the heat sink 25 may be pressed against the heat generation component 221 from the sub substrate 27 side without arranging a base member and another member such as a column around the heat generation component 221 on the main substrate 22. As a result, the region for mounting another component (for example, electronic components 222) may be sufficiently ensured around the heat generation component 221 against which the heat sink 25 is pressed.

In the transmission device 1 and the PIU 20 according to the embodiment, the pressing mechanisms 30 include the columnar members 31 and the springs 32. The columnar members 31 have the base ends 311 arranged on the sub substrate 27, extend to the lower side of the sub substrate 27, and are engaged with the heat sink 25. The springs 32 are provided on the outer circumferences of the columnar members 31 and abut against the lower surface 27b of the sub substrate 27, which opposes the main substrate 22, and the heat sink 25 to press the heat sink 25 against the heat generation component 221 along the extension direction of the columnar members 31.

The configurations of the transmission device 1 and the PIU 20 enable the heat sink 25 to be stably pressed against the heat generation component 221.

In the transmission device 1 and the PIU 20 according to the embodiment, the columnar members 31 are fixed to the sub substrate 27 by mounting the upper nut members 312 and the lower nut members 313 on the base ends 311 inserted through the holes 27a of the sub substrate 27 so as to interpose the sub substrate 27 therebetween. The upper buffer members 314 are inserted through between the upper nut members 312 and the upper surface 27c of the sub substrate 27 and the lower buffer members 315 are inserted through between the lower nut members 313 and the lower surface 27b of the sub substrate 27.

The configurations of the transmission device 1 and the PIU 20 enable the upper buffer members 314 and the lower buffer members 315 to absorb the force which acts on the heat sink 25 in the gravity direction and is transmitted to the columnar members 31 in falling of the PIU 20. As a result, the impact that is applied to the heat generation component 221 from the heat sink 25 is relieved and the bumping is avoided.

### Second Embodiment

A second embodiment relates to variations of the columnar members in the pressing mechanisms in the first embodiment.

[Configuration of PIU 20]

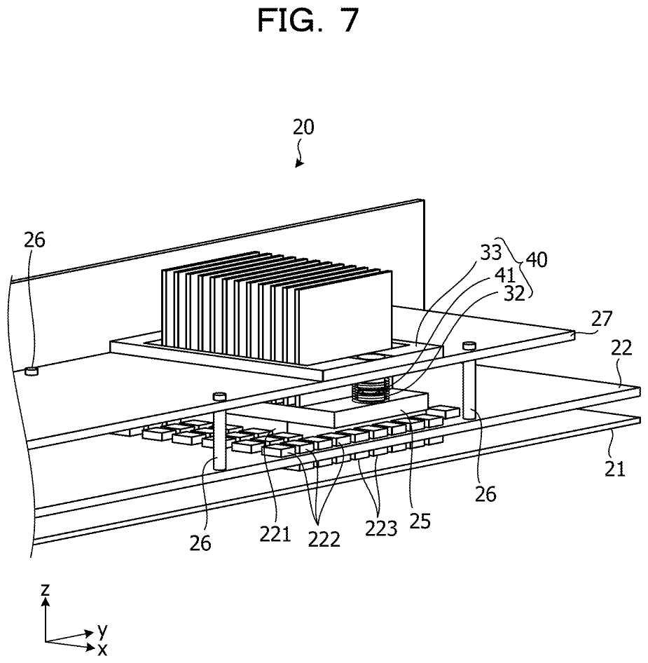

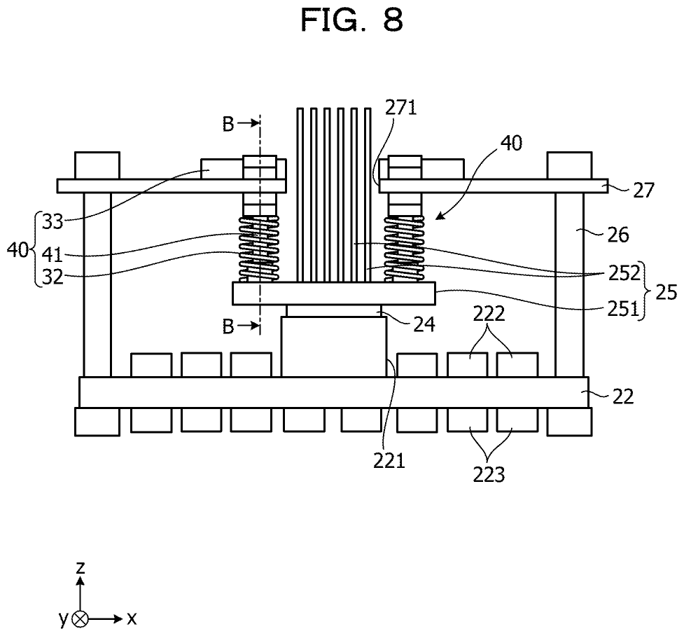

FIG. 7 is a perspective view illustrating an example of an internal configuration of a PIU 20 according to the second embodiment. FIG. 8 is a front view illustrating an example of the internal configuration of the PIU 20 according to the second embodiment.

As illustrated in FIG. 7 and FIG. 8, the PIU 20 includes pressing mechanisms 40.

[Configuration of Pressing Mechanisms 40]

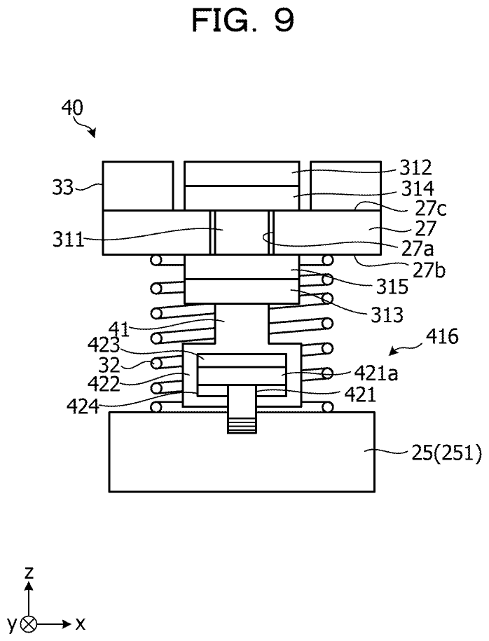

FIG. 9 is a side cross-sectional view illustrating an example of the configuration of the pressing mechanism 40 according to the second embodiment. The side cross-sectional view illustrated in FIG. 9 corresponds to a cross-sectional view cut along arrows B-B in FIG. 8. As illustrated in FIG. 7 and FIG. 8, the pressing mechanisms 40 include columnar members 41, the springs 32, and the reinforcing plates 33.

The columnar members 41 have the base ends 311 arranged on the sub substrate 27, extend to the lower side of the sub substrate 27, and are engaged with the heat sink 25.

An engagement mode between the columnar member 41 and the heat sink 25 will be described in detail with reference to FIG. 9. The columnar member 41 includes a screw portion 416 which is engaged with a screw hole formed in the heat sink 25. The screw portion 416 has a screw main body portion 421 and a screw case portion 422.

The screw main body portion 421 is engaged with the screw hole formed in the heat sink 25. The screw case portion 422 accommodates therein a head 421a of the screw main body portion 421 so as to be movable in the up-down direction.

Buffer members are inserted through between each of the upper surface and the lower surface of the head 421a of the screw main body portion 421 and inner wall surfaces of the screw case portion 422. For example, upper buffer member 423 is inserted through between the upper surface of the head 421a of the screw main body portion 421 and inner wall surfaces of the screw case portion 422, and lower buffer member 424 is inserted through between the lower surface of the head 421a of the screw main body portion 421 and the inner wall surfaces of the screw case portion 422. The upper buffer member 423 and the lower buffer member 424 have functions of absorbing force which acts on the heat sink 25 in the gravity direction (up-down direction in FIG. 9) and is transmitted to the screw main body portion 421. The upper buffer member 423 and the lower buffer member 424 are examples of a second buffer member.

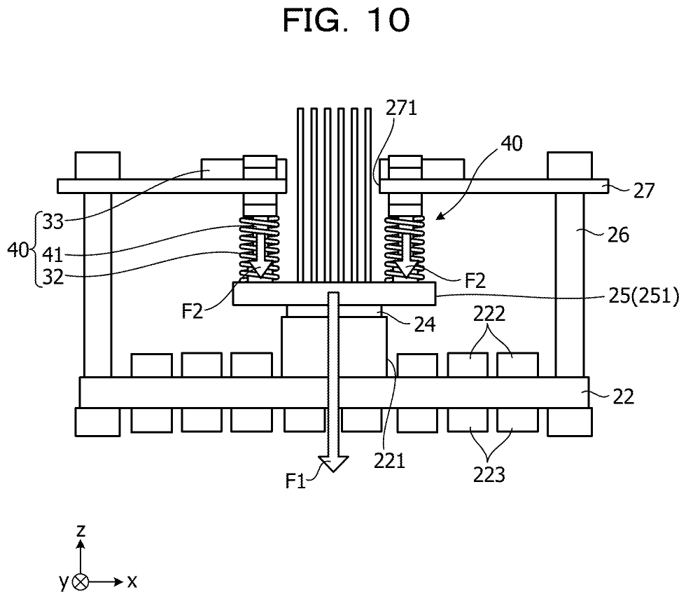

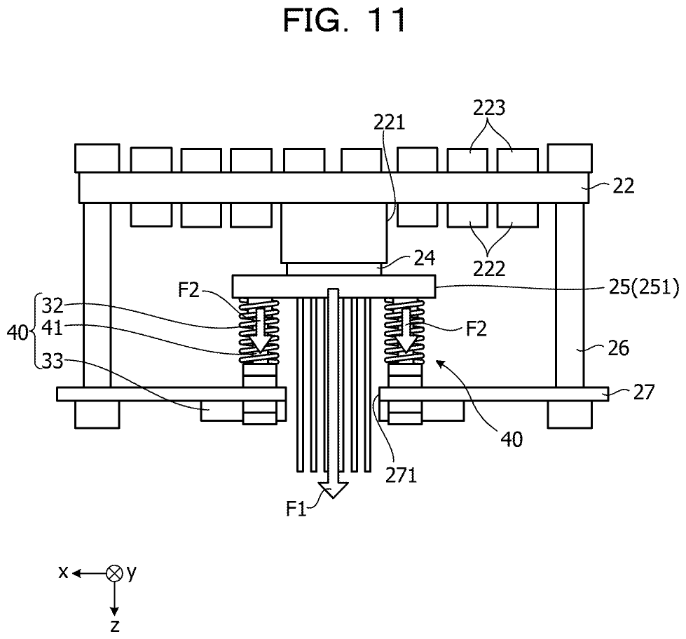

Next, the functions of the upper buffer members 423 and the lower buffer members 424 as the second buffer member will be described with reference to FIG. 10 and FIG. 11. FIG. 10 is a view (part 1) for explaining the functions of the first buffer member and the second buffer member. FIG. 10 illustrates a mode in which the PIU 20 falls on the ground in a state where the upper surface of the main substrate 22 (for example, surface of main substrate 22 on which heat generation component 221 is arranged) faces the direction on the opposite side to the ground. When the PIU 20 falls on the ground in the mode illustrated in FIG. 10, force F1 acts on the heat sink 25 in the gravity direction (downward direction in FIG. 10). The force F1 is transmitted, as forces F2, to the screw main body portions 421 engaged with the screw holes in the heat sink 25, the columnar members 41, and the upper nut members 312 mounted on the base ends 311 of the columnar members 41. When the forces F2 are transmitted to the screw main body portions 421, the lower buffer members 424 inserted through between the lower surfaces of the heads 421a of the screw main body portions 421 and the inner wall surfaces of the screw case portions 422 elastically contract and absorb the forces F2. When the forces F2 are transmitted to the upper nut members 312, the upper buffer members 314 inserted through between the upper nut members 312 and the upper surface 27c of the sub substrate 27 elastically contract and absorb the forces F2. The upper buffer members 314 and the lower buffer members 424 may thereby suppress movement of the heat sink 25 in the gravity direction (downward direction in FIG. 10). As a result, impact that is applied to the heat generation component 221 from the heat sink 25 is relieved.

FIG. 11 is a view (part 2) for explaining the functions of the first buffer member and the second buffer member. FIG. 11 illustrates a mode in which the PIU 20 falls on the ground in a state where the upper surface of the main substrate 22 (for example, surface of main substrate 22 on which heat generation component 221 is arranged) faces the direction of the ground. When the PIU 20 falls on the ground in the mode illustrated in FIG. 11, force F1 acts on the heat sink 25 in the gravity direction (downward direction in FIG. 11). The force F1 is transmitted, as forces F2, to the screw main body portions 421 engaged with the screw holes in the heat sink 25, the columnar members 41, and the lower nut members 313 mounted on the base ends 311 of the columnar members 41. When the forces F2 are transmitted to the screw main body portions 421, the upper buffer members 423 inserted through between the upper surfaces of the heads 421a of the screw main body portions 421 and the inner wall surfaces of the screw case portions 422 elastically contract and absorb the forces F2. When the forces F2 are transmitted to the lower nut members 313, the lower buffer members 315 inserted through between the lower nut members 313 and the lower surface 27b of the sub substrate 27 elastically contract and absorb the forces F2. The lower buffer members 315 and the upper buffer members 423 may thereby suppress movement of the heat sink 25 in the gravity direction (downward direction in FIG. 11) and avoid contraction of the springs 32 with the movement of the heat sink 25. As a result, the phenomenon (so-called bumping) that the heat sink 25 and the heat generation component 221 collide with each other with restoration of the springs 32 is avoided.

As described above, in the transmission device 1 and the PIU 20 according to the embodiment, the pressing mechanisms 40 include the columnar members 41 and the springs 32. The columnar members 41 have the screw portions 416. The screw portions 416 have the screw main body portions 421 and the screw case portions 422. The screw main body portion 421 is engaged with the screw hole formed in the heat sink 25. The screw case portions 422 accommodate therein the heads 421a of the screw main body portions 421 so as to be movable in the up-down direction. For example, the upper buffer members 423 are inserted through between the upper surfaces of the heads 421a of the screw main body portions 421 and the inner wall surfaces of the screw case portions 422, and the lower buffer members 424 are inserted through between the lower surfaces of the heads 421a of the screw main body portions 421 and the inner wall surfaces of the screw case portions 422.

The configurations of the transmission device 1 and the PIU 20 enable the upper buffer members 423 and the lower buffer members 424 to absorb the force which acts on the heat sink 25 in the gravity direction and is transmitted to the screw main body portions 421 in falling of the PIU 20. As a result, the impact that is applied to the heat generation component 221 from the heat sink 25 is relieved and the bumping is avoided.

### Third Embodiment

A third embodiment relates to variations of the columnar members and the reinforcing plates in the pressing mechanisms in the first embodiment.

[Configuration of PIU 20]

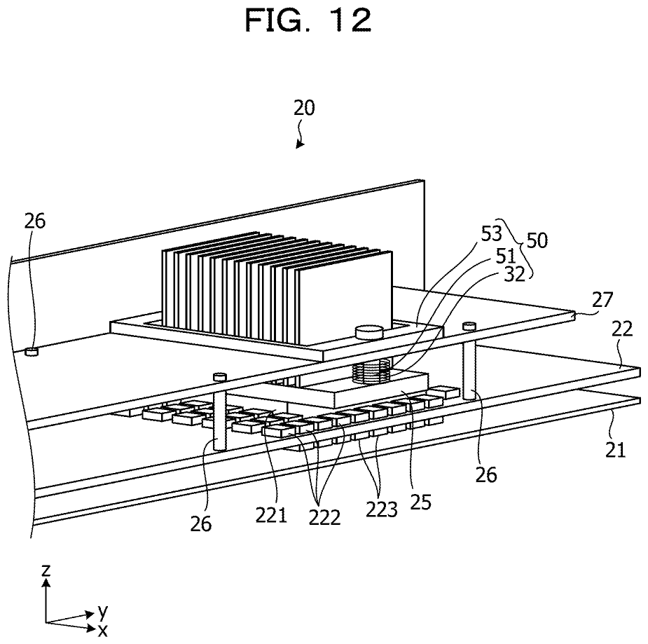

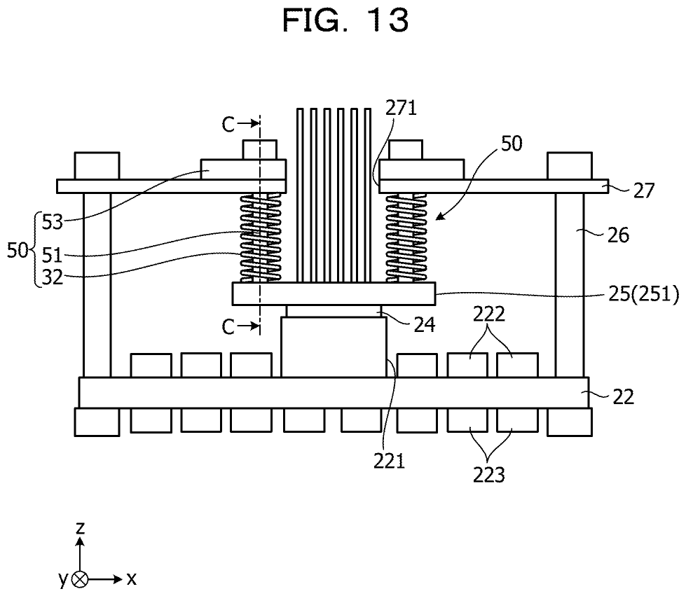

FIG. 12 is a perspective view illustrating an example of the internal configuration of a PIU 20 according to the third embodiment. FIG. 13 is a front view illustrating an example of the internal configuration of the PIU 20 according to the third embodiment.

As illustrated in FIG. 12 and FIG. 13, the PIU 20 includes pressing mechanisms 50.

[Configuration of Pressing Mechanisms 50]

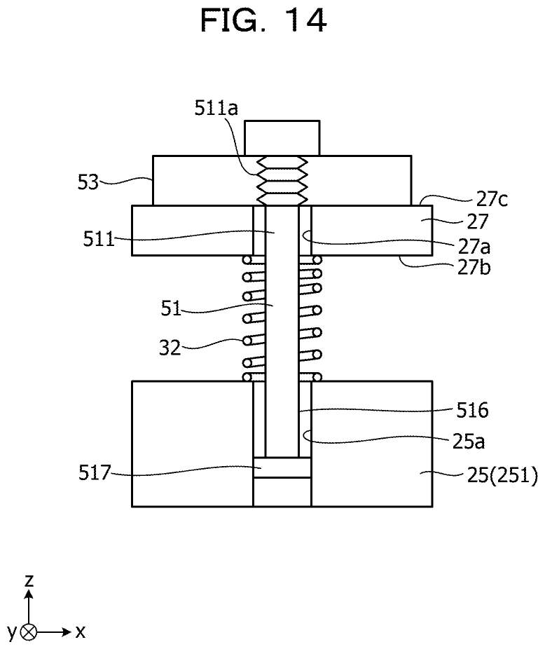

FIG. 14 is a side cross-sectional view illustrating an example of the configuration of the pressing mechanism 50 according to the third embodiment. The side cross-sectional view illustrated in FIG. 14 corresponds to a cross-sectional view cut along arrows C-C in FIG. 13. As illustrated in FIG. 12 to FIG. 14, the pressing mechanisms 50 include columnar members 51, the springs 32, and reinforcing plates 53.

The columnar members 51 have base ends 511 arranged on the sub substrate 27, extend to the lower side of the sub substrate 27, and are engaged with the heat sink 25.

The reinforcing plates 53 cover at least regions of the upper surface 27c of the sub substrate 27 on the opposite side to the main substrate 22, which correspond to the springs 32.

An arrangement mode of the columnar member 51 on the sub substrate 27 and an engagement mode between the columnar member 51 and the heat sink 25 will be described in detail with reference to FIG. 14. A hole 27a through which a base end 511 of the columnar member 51 is inserted is formed in the sub substrate 27. A screw groove 511a corresponding to a screw hole of the reinforcing plate 53 is formed in the base end 511 of the columnar member 51. The columnar member 51 is fixed to the sub substrate 27 by fixing of the base end 511 to the reinforcing plate 53.

The columnar member 51 has a tip portion 516 which is engaged with a recess 25a formed in the heat sink 25. Engagement between the tip portion 516 of the columnar member 51 and the recess 25a avoids positional deviation between the columnar member 51 and the heat sink 25 and the elastic force of the spring 32 is efficiently transmitted to the heat sink 25 along the extension direction of the columnar member 51.

A buffer member 517 is inserted through between the tip portion 516 of the columnar member 51 and the bottom surface of the recess 25a. The buffer member 517 has a function of absorbing force which acts on the heat sink 25 in the gravity direction (up-down direction in FIG. 14) and is transmitted to the columnar member 51. The buffer member 517 is an example of a third buffer member.

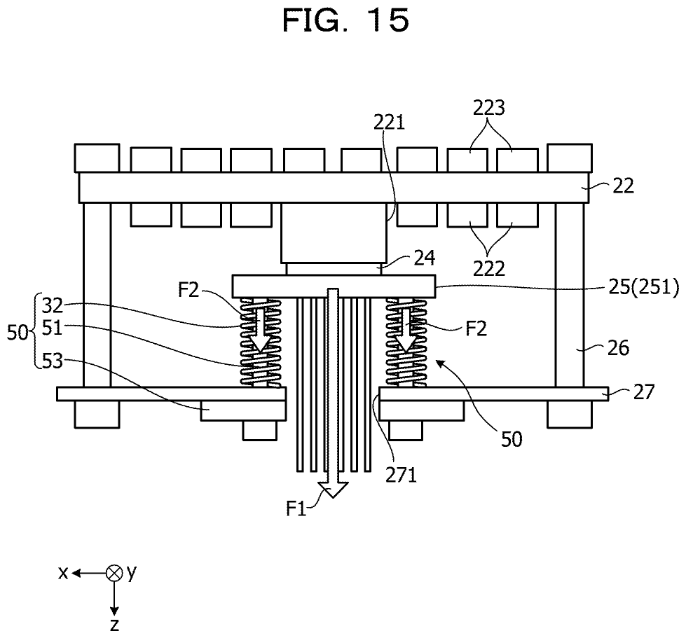

Next, the function of the buffer members 517 as the third buffer member will be described with reference to FIG. 15. FIG. 15 is a view for explaining the function of the third buffer member. FIG. 15 illustrates a mode in which the PIU 20 falls on the ground in a state where the upper surface of the main substrate 22 (for example, the surface of the main substrate 22 on which the heat generation component 221 is arranged) faces the direction of the ground. When the PIU 20 falls on the ground in the mode illustrated in FIG. 15, force F1 acts on the heat sink 25 in the gravity direction (downward direction in FIG. 15). The force F1 is transmitted, as forces F2, to the tip portions 516 of the columnar members 51 engaged with the recesses 25a in the heat sink 25. When the forces F2 are transmitted to the tip portions 516 of the columnar members 51, the buffer members 517 inserted through between the tip portions 516 of the columnar members 51 and the bottom surfaces of the recesses 25a elastically contract and absorb the forces F2. The buffer members 517 may thereby suppress movement of the heat sink 25 in the gravity direction (downward direction in FIG. 14) and avoid contraction of the springs 32 with the movement of the heat sink 25. As a result, the phenomenon (so-called bumping) that the heat sink 25 and the heat generation component 221 collide with each other with restoration of the springs 32 is avoided.

As described above, in the transmission device 1 and the PIU 20 according to the embodiment, the pressing mechanisms 50 include the columnar members 51, the springs 32, and the reinforcing plates 53. The reinforcing plates 53 cover at least the regions of the upper surface 27c of the sub substrate 27 on the opposite side to the main substrate 22, which correspond to the springs 32. The columnar members 51 are fixed to the sub substrate 27 by fixing of the base ends 511 to the reinforcing plates 53. The columnar members 51 have the tip portions 516 which are engaged with the recesses 25a formed in the heat sink 25. The buffer members 517 are inserted through between the tip portions 516 of the columnar members 51 and the bottom surfaces of the recesses 25a.

The configurations of the transmission device 1 and the PIU 20 enable the buffer members 517 to absorb the force which acts on the heat sink 25 in the gravity direction and is transmitted to the columnar members 51 in falling of the PIU 20. As a result, the bumping is avoided.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A transmission device comprising:
a first substrate on which a heat generation component is arranged;
a heat sink that is placed on the heat generation component;
a second substrate that is arranged above a surface of the first substrate on which the heat generation component is arranged; and
a pressing mechanism that presses the heat sink against the heat generation component arranged on the first substrate from the second substrate side.

2. The transmission device according to claim 1, wherein
the pressing mechanism includes:
a columnar member that has a base end arranged on the second substrate, extends to a lower side of the second substrate, and is engaged with the heat sink; and
an elastic member that is provided on an outer circumference of the columnar member, abuts against a lower surface of the second substrate, which opposes the first substrate, and the heat sink, and presses the heat sink against the heat generation component along an extension direction of the columnar member.

3. The transmission device according to claim 2, wherein
a hole through which the base end of the columnar member is inserted is formed in the second substrate,
the columnar member is fixed to the second substrate by mounting a pair of nut members on the base end of the columnar member, which has been inserted through the hole of the second substrate, so as to interpose the second substrate, and
a first buffer member is inserted through between each of the pair of nut members and the second substrate.

4. The transmission device according to claim 2, wherein
the columnar member includes a screw portion which is engaged with a screw hole formed in the heat sink.

5. The transmission device according to claim 4, wherein
the screw portion has a screw main body portion which is engaged with the screw hole formed in the heat sink, a screw case portion which accommodates a head of the screw main body portion, and a second buffer member which is inserted through between each of an upper surface and a lower surface of the head of the screw main body portion and an inner wall surface of the screw case portion.

6. The transmission device according to claim 2, wherein
the pressing mechanism further includes a reinforcing plate which covers at least a region of an upper surface of the second substrate on an opposite side to the first substrate, which corresponds to the elastic member.

7. The transmission device according to claim 2, wherein
the pressing mechanism further includes a reinforcing plate which covers at least a region of an upper surface of the second substrate on an opposite side to the first substrate, which corresponds to the elastic member,
the columnar member is fixed to the second substrate by fixing of the base end of the columnar member to the reinforcing plate,
the second substrate has a hole through which the base end of the columnar member is inserted,
the columnar member has a tip portion which is engaged with a recess formed in the heat sink, and
a third buffer member is inserted through between the tip portion of the columnar member and a bottom surface of the recess.

8. A plug-in unit comprising:
a first substrate on which a heat generation component is arranged;
a heat sink that is placed on the heat generation component;
a second substrate that is arranged above a surface of the first substrate on which the heat generation component is arranged; and
a pressing mechanism that presses the heat sink against the heat generation component arranged on the first substrate from the second substrate side.

9. The plug-in unit according to claim 8, wherein
the pressing mechanism includes:
a columnar member that has a base end arranged on the second substrate, extends to a lower side of the second substrate, and is engaged with the heat sink; and
an elastic member that is provided on an outer circumference of the columnar member, abuts against a lower surface of the second substrate, which opposes the first substrate, and the heat sink, and presses the heat sink against the heat generation component along an extension direction of the columnar member.

10. The plug-in unit according to claim 9, wherein
a hole through which the base end of the columnar member is inserted is formed in the second substrate,
the columnar member is fixed to the second substrate by mounting a pair of nut members on the base end of the columnar member, which has been inserted through the hole of the second substrate, so as to interpose the second substrate, and
a first buffer member is inserted through between each of the pair of nut members and the second substrate.

11. The plug-in unit according to claim 9, wherein
the columnar member includes a screw portion which is engaged with a screw hole formed in the heat sink.

12. The plug-in unit according to claim 11, wherein
the screw portion has a screw main body portion which is engaged with the screw hole formed in the heat sink, a screw case portion which accommodates a head of the screw main body portion, and a second buffer member which is inserted through between each of an upper surface and a lower surface of the head of the screw main body portion and an inner wall surface of the screw case portion.

13. The plug-in unit according to claim 9, wherein
the pressing mechanism further includes a reinforcing plate which covers at least a region of an upper surface of the second substrate on an opposite side to the first substrate, which corresponds to the elastic member.

14. The plug-in unit according to claim 9, wherein
the pressing mechanism further includes a reinforcing plate which covers at least a region of an upper surface of the second substrate on an opposite side to the first substrate, which corresponds to the elastic member,
the columnar member is fixed to the second substrate by fixing of the base end of the columnar member to the reinforcing plate,
the second substrate has a hole through which the base end of the columnar member is inserted,
the columnar member has a tip portion which is engaged with a recess formed in the heat sink, and
a third buffer member is inserted through between the tip portion of the columnar member and a bottom surface of the recess.
